(19) United States
(12) Patent Application Publication
(10) Pub. No.: US 2023/0106356 A1
(43) Pub. Date: Apr. 6, 2023

(54) TERMINAL, ELECTRONIC COMPONENT PACKAGE, AND MANUFACTURING METHOD OF TERMINAL

(71) Applicant: Murata Manufacturing Co., Ltd., Kyoto-fu (JP)

(72) Inventor: Yuji KIMURA, Nagaokakyo-shi (JP)

(73) Assignee: Murata Manufacturing Co., Ltd., Kyoto-fu (JP)

(21) Appl. No.: 18/061,903

(22) Filed: Dec. 5, 2022

Related U.S. Application Data
(63) Continuation of application No. PCT/JP2021/036409, filed on Oct. 1, 2021.

(30) Foreign Application Priority Data
Jan. 5, 2021 (JP) 2021-000362

(51) Int. Cl. H01M 50/552; H01M 50/562; H01M 50/588; H01M 50/59

(52) U.S. Cl. CPC H01M 50/552; H01M 50/562; H01M 50/588; H01M 50/59

(57) ABSTRACT

A terminal includes a substrate made of metal, an electrode portion that is formed of the same material as the substrate and functions as an electrode, and an insulating resin that is provided between the substrate and the electrode portion so as to surround the electrode portion and insulates the substrate and the electrode portion from each other.

### CROSS-REFERENCE TO RELATED APPLICATIONS

This application claims benefit of priority to International Patent Application No. PCT/JP2021/036409, filed Oct. 1, 2021, and to Japanese Patent Application No. 2021-000362, filed Jan. 5, 2021, the entire contents of each are incorporated herein by reference.

### BACKGROUND

### Technical Field

The present disclosure relates to a terminal, an electronic component package including a terminal, and a manufacturing method of a terminal.

### Background Art

As a terminal for electrically connecting to an electronic component and the like, Japanese Unexamined Patent Application Publication No. 2000-200857 discloses a terminal used when an electronic component and the like are sealed in a case. In the terminal, an insulation film is provided on a surface of core metal, having a predetermined shape, in which a hole for a conductive line passing from the inside to the outside is formed, an internal conductor film is formed on the insulation film on an inner surface of the core metal, a conductive line is formed in the hole for a conductive line, and an external conductor film is formed on the insulation film on an outer surface of the core metal. The internal conductor film, the conductive line, and the external conductor film are interconnected. The conductive line is formed by being applied with a conductive paste and being fired.

### SUMMARY

However, in the terminal for sealing described in Japanese Unexamined Patent Application Publication No. 2000-200857, since the core metal and the conductive line are formed of different materials, for example, when an electronic component is connected to the terminal by solder or the like, peeling of the conductive line may occur due to a difference in thermal expansion between the core metal and the conductive line, and the shape may deform.

Accordingly, the present disclosure provides a terminal that can suppress deformation caused by a difference in thermal expansion between different portions when being heated, an electronic component package including such a terminal, and a manufacturing method of such a terminal.

A terminal of the present disclosure includes a substrate made of metal, an electrode portion that is formed of the same material as the substrate and functions as an electrode, and an insulating resin that is provided between the substrate and the electrode portion to surround the electrode portion and insulates the substrate and the electrode portion from each other.

An electronic component package of the present disclosure includes a sealed container including the above-described terminal, and an electronic component element that is disposed in the sealed container while being electrically connected to the electrode portion. A manufacturing method of a terminal of the present disclosure is a manufacturing method of a terminal including a substrate made of metal, an electrode portion that is formed of the same material as the substrate and functions as an electrode, and an insulating resin that is provided between the substrate and the electrode portion to surround the electrode portion and insulates the substrate and the electrode portion from each other. The manufacturing method includes providing a groove for dividing a mother substrate made of metal into the substrate and the electrode portion, and disposing the insulating resin in the groove.

According to the terminal of the present disclosure, since the electrode portion that functions as an electrode is formed of the same material as the substrate made of metal, no difference in thermal expansion is generated between the substrate and the electrode portion. As a result, for example, when the terminal is heated in such a case that an electronic component element is connected to the terminal by solder or the like, deformation caused by the difference in thermal expansion between the substrate and the electrode portion can be suppressed.

The electronic component package of the present disclosure has a configuration in which an electronic component element is disposed in a sealed container including the terminal whose deformation is suppressed. Therefore, the sealing property of the sealed container can be maintained.

According to the manufacturing method of a terminal of the present disclosure, since firing is not included, there is no risk of deforming the substrate by firing.

### BRIEF DESCRIPTION OF THE DRAWINGS

FIG. 1 is a perspective view schematically illustrating a shape of a terminal according to a first embodiment, FIG. 1A illustrates a first main surface side, and FIG. 1B illustrates a second main surface side;

FIG. 2 is a schematic sectional view of the terminal illustrated in FIG. 1 cut along line

FIGS. 3A to 3E are views for explaining a manufacturing method of the terminal according to the first embodiment;

FIG. 4 is a schematic sectional view of a terminal according to a second embodiment;

FIGS. 5A to 5F are views for explaining a manufacturing method of the terminal according to the second embodiment;

FIG. 6 is a schematic sectional view of a terminal according to a third embodiment;

FIGS. 7A to 7E are views for explaining a manufacturing method of the terminal according to the third embodiment;

FIG. 8 is a perspective view schematically illustrating a shape of a terminal according to a fourth embodiment;

FIG. 9 is a schematic sectional view of the terminal illustrated in FIG. 8 cut along line IX-IX;

FIGS. 10A to 10F are views for explaining a manufacturing method of the terminal according to the fourth embodiment;

FIG. 11 is a perspective view schematically illustrating a shape of an electronic component package according to a fifth embodiment;

FIG. 12 is a schematic sectional view of the package illustrated in FIG. 11 cut along line XII-XII;

FIG. 13A is an exploded view of the electronic component package when the terminal constitutes a lid, and FIG. 13B is an exploded view of the electronic component package when the terminal constitutes a part of a housing; and

FIG. 14 is a schematic sectional view when the electronic component package is formed using the terminal according to the fourth embodiment.

### DETAILED DESCRIPTION

Hereinafter, embodiments of the present disclosure will be illustrated, and features of the present disclosure will be described in detail.

### First Embodiment

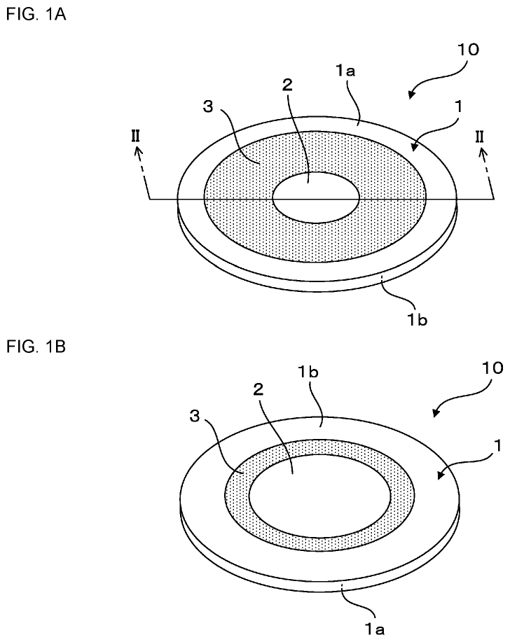

FIG. 1 is a perspective view schematically illustrating a shape of a terminal 10 according to a first embodiment, FIG. 1A illustrates a first main surface 1a side, and FIG. 1B illustrates a second main surface 1b side. FIG. 2 is a schematic sectional view of the terminal 10 illustrated in FIG. 1 cut along line II-II.

The terminal 10 according to the first embodiment includes a substrate 1 made of metal, an electrode portion 2, and an insulating resin 3.

As illustrated in FIG. 1, the terminal 10 according to the present embodiment has a flat plate-like shape and has a circular shape when viewed in a thickness direction. However, the shape when viewed in the thickness direction is not limited to a circular shape and can be another shape such as a rectangular shape or an elliptical shape.

In the present embodiment, the substrate 1 made of metal is made of SUS316L stainless steel. However, the metal forming the substrate 1 is not limited to SUS316L stainless steel and may be stainless steel such as SUS304 stainless steel or may be aluminum, copper, nickel, or the like.

The substrate 1 has a first main surface 1a and a second main surface 1b facing each other in the thickness direction. The thickness of the substrate 1 is, for example, equal to or more than 0.03 mm and equal to or less than 0.3 mm (i.e., from 0.03 mm to 0.3 mm).

The electrode portion 2 is formed of the same material as the substrate 1 and functions as an electrode. In the present embodiment, the electrode portion 2 is formed of the same SUS316L stainless steel as the substrate 1. In the present embodiment, there is only one electrode portion 2, but a plurality of electrode portions 2 may be provided in the terminal 10.

The insulating resin 3 is provided between the substrate 1 and the electrode portion 2 so as to surround the electrode portion 2 and insulates the substrate 1 and the electrode portion 2 from each other. That is, in a plane direction of the terminal 10 having the flat plate-like shape, the electrode portion 2 is located inside the insulating resin 3, and the substrate 1 is located outside the insulating resin 3. As the insulating resin 3, for example, thermosetting epoxy resin can be used. However, the insulating resin is not limited to thermosetting resin, and thermoplastic resin may be used, or UV curing resin may be used.

In the present embodiment, as illustrated in FIG. 1A and FIG. 2, the insulating resin 3 is also provided on a part of a surface of the substrate 1 and a part of a surface of the electrode portion 2 on the first main surface 1a side of the substrate 1.

In the terminal 10 according to the present embodiment, since the electrode portion 2 that functions as an electrode is formed of the same material as the substrate 1 made of metal, no difference in thermal expansion is generated between the substrate 1 and the electrode portion 2. As a result, for example, when the terminal 10 is heated in such a case that an electronic component element is connected to the terminal 10 by solder or the like, deformation caused by the difference in thermal expansion between the substrate 1 and the electrode portion 2 can be suppressed.

As will be described later, the terminal 10 according to the present embodiment can be used as a part of a sealed container of an electronic component package in which an electronic component element is accommodated in the sealed container. In such a case, as described above, since a configuration in which deformation of the terminal 10 is suppressed is adopted, the sealing property of the sealed container can be maintained.

Manufacturing Method

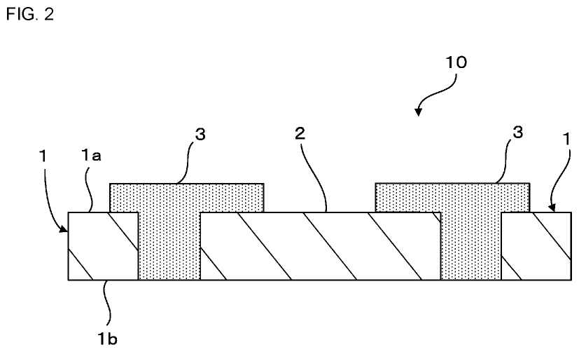

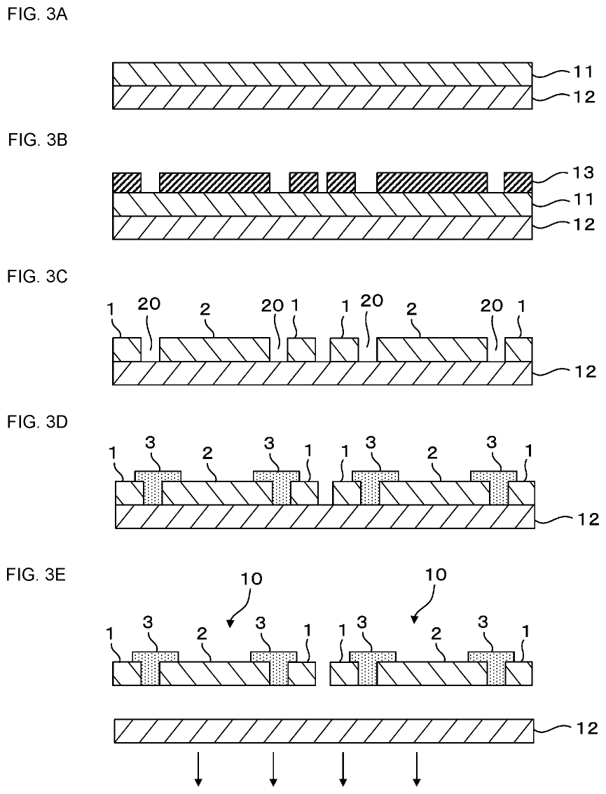

With reference to FIG. 3, an example of a manufacturing method of the terminal 10 according to the first embodiment will be described.

First, as illustrated in FIG. 3A, a mother substrate 11 made of metal is adhered and fixed onto a supporting substrate 12. In the present embodiment, the mother substrate 11 is a substrate for forming the substrate 1 and the electrode portion 2 and is made of SUS316L stainless steel. The supporting substrate 12 is made of, for example, alumina. The method of adhering and fixing the mother substrate 11 to the supporting substrate 12 is not particularly limited, and the mother substrate 11 is adhered and fixed by using, for example, an adhesive sheet. In this case, as the adhesive sheet, for example, a foam adhesive sheet that can be peeled by heating (for example, at 180° C.) can be used.

Subsequently, a groove for dividing the mother substrate 11 made of metal into the substrate 1 and the electrode portion 2 is provided. Here, the following method is used to provide a groove.

A resist 13 is disposed on the mother substrate 11, and exposure and development are performed using a photomask to perform patterning on the resist 13 (FIG. 3B). Here, the resist 13 is patterned such that a portion of the mother substrate 11 at which a groove for dividing the mother substrate 11 into the substrate 1 and the electrode portion 2 is to be provided is exposed.

Subsequently, after etching is performed on the mother substrate 11 by using, for example, ferric chloride, the resist 13 is removed. As a result, a groove 20 is formed in the mother substrate 11 to divide the mother substrate 11 into the substrate 1 and the electrode portion 2, and the substrate 1 and the electrode portion 2 are formed on the supporting substrate 12 (FIG. 3C).

Note that FIG. 3C illustrates a state in which substrates 1 and electrode portions 2 for forming two terminals 10 are formed on the supporting substrate 12. That is, in the etching here, not only the substrate 1 and the electrode portion 2 for forming one terminal 10 are formed from the mother substrate 11, but also individualizing is performed to obtain a plurality of terminals 10 at the same time. However, individualizing may be performed by punching at the end without performing etching for individualizing.

Subsequently, the groove 20 formed in the mother substrate 11 is filled (provided) with insulating resin. Filling the groove 20 with insulating resin is performed by, for example, printing, but other methods such as dispensing may be used. The insulating resin is also applied to a part of a surface of the substrate 1 and a part of a surface of the electrode portion 2 on the opposite side of the supporting substrate 12.

As the insulating resin, resin that has excellent adhesion to the substrate 1 and the electrode portion 2 is preferably used. In the description here, as the insulating resin, thermosetting resin is used. However, as described above, as the insulating resin, thermoplastic resin or UV curing resin may be used.

After the insulating resin is applied, the insulating resin is cured by heating. For example, the insulating resin is cured at 140° C. for one hour. As a result, the insulating resin 3 that forms the terminal 10 is formed (FIG. 3D). Note that in consideration of thermal expansion and thermal contraction of the substrate 1 and the electrode portion 2, the insulating resin 3 after being cured is preferably elastic.

Finally, the supporting substrate 12 is peeled (FIG. 3E). As described above, when a foam adhesive sheet that can be peeled by heating is used to adhere and fix the mother substrate 11 to the supporting substrate 12, the supporting substrate 12 can be peeled by heating. Note that for the foam adhesive sheet that can be peeled by heating, an adhesive sheet having adhesion that is not decreased under the heating condition for curing the insulating resin needs to be used.

Through the above-described steps, the terminal 10 according to the present embodiment is manufactured. According to the above-described manufacturing method, since the substrate 1 and the electrode portion 2 are formed from the mother substrate 11, the electrode portion 2 formed of the same material as the substrate 1 can be easily formed. In addition, when the electrode portion 2 is formed, a step of applying and firing a conductive paste, which is performed in the manufacturing method of a terminal described in Japanese Unexamined Patent Application Publication No. 2000-200857, is unnecessary. Therefore, a thermal treatment at a high temperature such as in firing a conductive paste is unnecessary, and deformation of the substrate 1 due to a high-temperature thermal treatment can be suppressed.

Note that from one mother substrate 11, one terminal 10 may be manufactured, or two or more terminals 10 may be manufactured.

### Second Embodiment

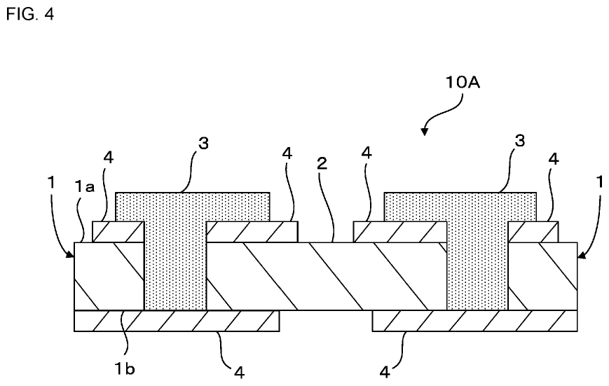

FIG. 4 is a schematic sectional view of a terminal 10A according to a second embodiment. The cutting position of the sectional view illustrated in FIG. 4 is the same as the cutting position of the schematic sectional view of the terminal 10 according to the first embodiment illustrated in FIG. 2.

The terminal 10A according to the second embodiment further includes an insulating film 4 in addition to the configuration of the terminal 10 according to the first embodiment. The insulating film 4 is provided between the insulating resin 3 provided on the first main surface 1a side of the substrate 1 and the substrate 1, between the insulating resin 3 provided on the first main surface 1a side of the substrate 1 and the electrode portion 2, and at a position where the insulating film 4 covers at least the insulating resin 3 on the second main surface 1b side facing the first main surface 1a of the substrate 1.

The insulating film 4 is a thin film formed by, for example, a low-temperature black chromium treatment. However, the insulating film 4 is not limited to a thin film formed by a low-temperature black chromium treatment and may be a film made of a ceramic or glass-based material. The insulating film 4 has a higher adhesion property to the substrate 1 and the electrode portion 2 than the insulating resin 3 and has a denser structure than the insulating resin 3. Note that the kind of the insulating film 4 provided on the first main surface 1a side of the substrate 1 may be different from the kind of the insulating film 4 provided on the second main surface 1b side. For example, when different insulation resistances are required on the first main surface 1a side and the second main surface 1b side of the substrate 1, the insulating films 4 having different insulation resistances may be provided on the first main surface 1a side and the second main surface 1b side, respectively. The thickness of each insulating film 4 may be, for example, equal to or more than 5 μm and equal to or less than 20 μm (i.e., from 5 μm to 20 μm).

The terminal 10A according to the present embodiment can also be used as a part of a sealed container of an electronic component package in which an electronic component element is disposed in the sealed container. In the same manner as the terminal 10 according to the first embodiment, in the terminal 10A according to the present embodiment, since the substrate 1 and the electrode portion 2 are formed of the same material, no difference in thermal expansion is generated between the substrate 1 and the electrode portion 2, and a sealed container having an excellent sealing property can be formed. In particular, for the following reasons, the terminal 10A according to the present embodiment can constitute a sealed container whose sealing property is further excellent compared to the terminal 10 according to the first embodiment.

Although the type of the electronic component element that is disposed in the sealed container is not particularly limited, an element, such as a battery, that generates gas may be disposed. As described above, in the terminal 10A according to the present embodiment, the insulating film 4 is provided between the insulating resin 3 provided on the first main surface 1a side of the substrate 1 and the substrate 1, between the insulating resin 3 provided on the first main surface 1a side of the substrate 1 and the electrode portion 2, and at a position where the insulating film 4 covers at least the insulating resin 3 on the second main surface 1b side of the substrate 1. Thus passing of gas between the insulating resin 3 provided on the first main surface 1a side of the substrate 1 and the substrate 1, between the insulating resin 3 provided on the first main surface 1a side of the substrate 1 and the electrode portion 2, and in the insulating resin 3 can be suppressed. As a result, leaking of gas that has been generated in the sealed container to the outside can be suppressed.

Note that in order to ensure a conduction path of the electrode portion 2, as illustrated in FIG. 4, the electrode portion 2 needs to be exposed on the first main surface 1a side and the second main surface 1b side. However, in a state where a surface of the electrode portion 2 is covered with the insulating film 4, when an electronic component element and the like are joined to the electrode portion 2 by welding, the insulating film 4 at the portion to be joined is eliminated, and thus the surface of the electrode portion 2 may be covered with the insulating film 4.

As an example of a modified configuration of the above-described terminal 10A, the insulating film 4 may be provided only between the insulating resin 3 provided on the first main surface 1a side of the substrate 1 and the substrate 1 and between the insulating resin 3 provided on the first main surface 1a side of the substrate 1 and the electrode portion 2. Also in such a configuration, passing of gas between the insulating resin 3 provided on the first main surface 1a side of the substrate 1 and the substrate 1 and between the insulating resin 3 provided on the first main surface 1a side of the substrate 1 and the electrode portion 2 can be suppressed, and thus compared to the terminal 10 according to the first embodiment, a sealed container whose sealing property is further excellent can be formed.

Manufacturing Method

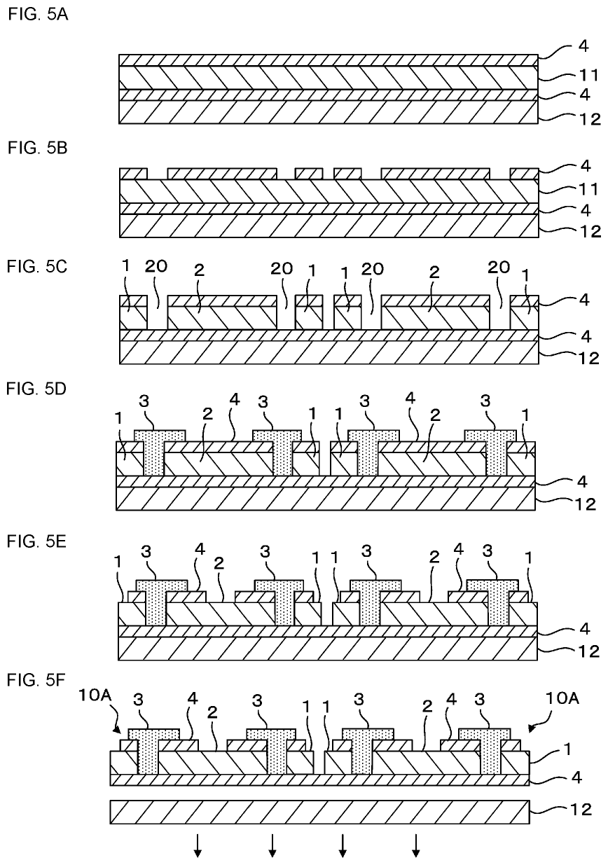

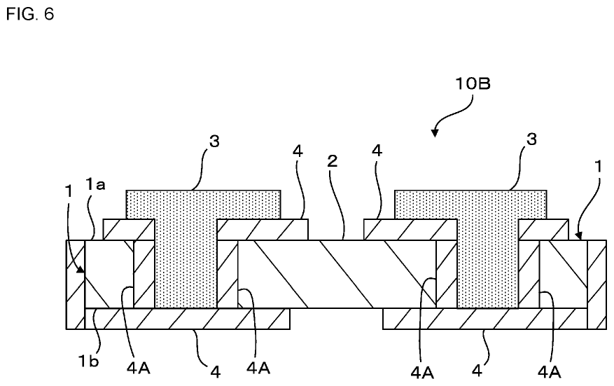

With reference to FIG. 5, an example of a manufacturing method of the terminal 10A according to the second embodiment will be described below. Note that a detailed description of the same steps as the manufacturing method of the terminal 10 according to the first embodiment will be omitted.

First, the insulating film 4 is formed on each surface of the mother substrate 11 made of metal and is adhered and fixed to the supporting substrate 12 (FIG. 5A). As an example, the insulating film 4 is formed by performing a low-temperature black chromium treatment on each surface of the mother substrate 11.

Subsequently, a part of the insulating film 4 is removed by a laser (FIG. 5B). A laser corresponding to the characteristics of the insulating film 4 to be removed shall be used, and for example, an YVO4 laser maker can be used. Note that the method of removing a part of the insulating film 4 is not limited to a method using a laser. However, by using a laser, it is possible to remove the insulating film 4 without using a resist, and the removal treatment can be easily performed on the insulating film 4.

Subsequently, by using the remaining insulating film 4 as a mask and performing etching on the mother substrate 11, the groove 20 for dividing the mother substrate 11 into the substrate 1 and the electrode portion 2 is provided (FIG. 5C). At this time, the insulating film 4 provided on the supporting substrate 12 side functions as a stopping layer of etching.

Note that during etching, in a case where the insulating film 4 provided on the supporting substrate 12 side is damaged, another insulating film may be provided on the bottom surface of the formed groove 20.

Alternatively, when the insulating film 4 that does not function as a mask during etching is used, a resist may be provided on the insulating film 4 and patterning may be performed.

Subsequently, the groove 20 formed in the mother substrate 11 is filled with insulating resin, and the resin is cured. As a result, the insulating resin 3 forming the terminal 10 is formed (FIG. 5D).

Subsequently, in order to expose a surface of the electrode portion 2, a laser is used to remove a part of the insulating film 4 provided on the surface of the electrode portion 2 (FIG. 5E). However, the method of removing a part of the insulating film 4 is not limited to a method using a laser. In addition, a part of the insulating film 4 provided on the substrate 1 other than the electrode portion 2 may be removed where necessary.

Finally, the supporting substrate 12 is peeled (FIG. 5F).

Note that in this state, the entire surface on the supporting substrate 12 side, of the surfaces of the electrode portion 2, is covered with the insulating film 4, but when the electrode portion 2 of the terminal 10A is joined to an electronic component element and the like by welding, the insulating film 4 is eliminated, and thus conduction can be obtained. However, after the supporting substrate 12 is peeled, a part of the insulating film 4 may be removed such that the surface of the electrode portion 2 on the supporting substrate 12 side is exposed. Alternatively, before the mother substrate 11 having the insulating film 4 formed on each surface is adhered and fixed to the supporting substrate 12, a part of the insulating film 4 may be removed such that the surface of the electrode portion 2 on the supporting substrate 12 side is exposed, and then the mother substrate 11 may be adhered and fixed to the supporting substrate 12.

Through the above-described steps, the terminal 10A according to the second embodiment can be manufactured.

### Third Embodiment

FIG. 6 is a schematic sectional view of a terminal 10B according to a third embodiment. The cutting position of the sectional view illustrated in FIG. 6 is the same as the cutting position of the schematic sectional view of the terminal 10 according to the first embodiment illustrated in FIG. 2.

In the terminal 10B according to the third embodiment, compared to the configuration of the terminal 10A according to the second embodiment, an insulating film 4A is also provided between the insulating resin 3 provided so as to surround the electrode portion 2 and the electrode portion 2 and between the insulating resin 3 provided so as to surround the electrode portion 2 and the substrate 1. In other words, the insulating film 4A is provided, in a plane direction of the terminal 10B having a flat plate-like shape, between the insulating resin 3 and the electrode portion 2 and between the insulating resin 3 and the substrate 1. As a type of the insulating film 4A, the same type as the insulating film 4 may be used, or a different type may be used.

In the terminal 10B according to the present embodiment, since the substrate 1 and the electrode portion 2 are formed of the same material, no difference in thermal expansion is generated between the substrate 1 and the electrode portion 2, and a sealed container having an excellent sealing property can be formed. In addition, in the same manner as the terminal 10A according to the second embodiment, the insulating film 4 is provided between the insulating resin 3 provided on the first main surface 1a side of the substrate 1 and the substrate 1, between the insulating resin 3 provided on the first main surface 1a side of the substrate 1 and the electrode portion 2, and at a position where the insulating film 4 covers at least the insulating resin 3 on the second main surface 1b side of the substrate 1. Thus, compared to the terminal 10 according to the first embodiment, a sealed container having further excellent sealing property can be formed. In particular, in the terminal 10B according to the present embodiment, the insulating film 4A is provided between the insulating resin 3 provided so as to surround the electrode portion 2 and the electrode portion 2 and between the insulating resin 3 provided so as to surround the electrode portion 2 and the substrate 1. As a result, insulation between the substrate 1 and the electrode portion 2 can be ensured, and thus electrical reliability of the terminal 10B is improved.

Manufacturing Method

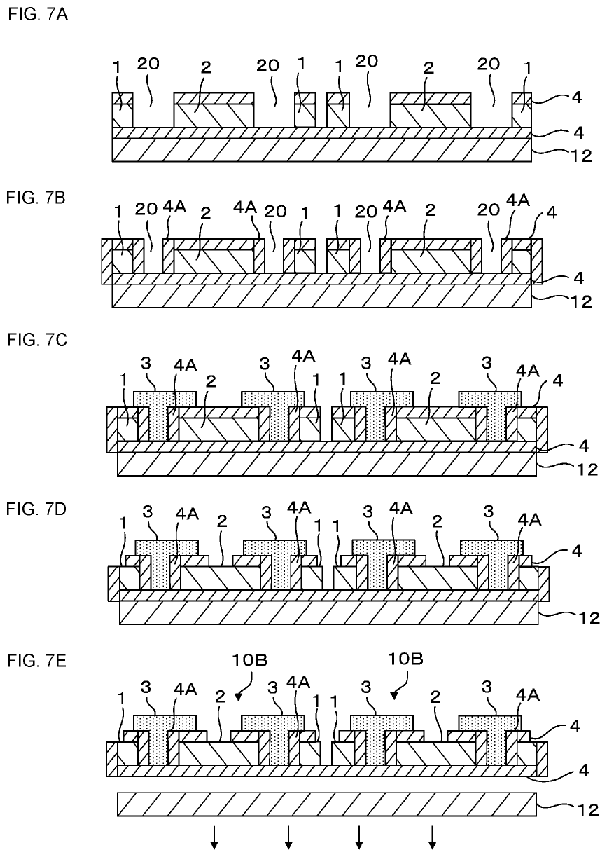

With reference to FIG. 7, an example of a manufacturing method of the terminal 10B according to the third embodiment will be described below. Note that a detailed description of the same steps as the manufacturing methods of the terminal 10 according to the first embodiment and the terminal 10A according to the second embodiment will be omitted.

First, the insulating film 4 is formed on each surface of the mother substrate 11 made of metal and is adhered and fixed to the supporting substrate 12, and a part of the insulating film 4 is removed by a laser, and then etching is performed on the mother substrate 11 by using the remaining insulating film 4 as a mask so as to provide the groove 20 for dividing the mother substrate 11 into the substrate 1 and the electrode portion 2. The steps thus far are the same as the steps in the manufacturing method of the terminal 10A according to the second embodiment, which have been described with reference to FIGS. 5A to 5C. FIG. 7A illustrates a state in which by performing etching on the mother substrate 11, the groove 20 for dividing the mother substrate 11 into the substrate 1 and the electrode portion 2 is provided.

Subsequently, using an electrodeposition resist, the insulating film 4A is formed around the substrate 1 and the electrode portion 2 (FIG. 7B). As a material for the insulating film 4A, an organic material may be used, or an inorganic material may be used. Alternatively, the insulating film 4A may be formed by a dry process such as sputtering or chemical vapor deposition (CVD).

Subsequently, the groove 20 formed in the mother substrate 11 is filled with insulating resin, and the resin is cured. As a result, the insulating resin 3 forming the terminal 10 is formed (FIG. 7C).

Subsequently, in order to expose a surface of the electrode portion 2, a laser is used to remove a part of the insulating film 4 provided on the surface of the electrode portion 2 (FIG. 7D). In addition, a part of the insulating film 4 provided on the substrate 1 may be removed where necessary.

Finally, the supporting substrate 12 is peeled (FIG. 7E).

Through the above-described steps, the terminal 10B according to the second embodiment can be manufactured. Note that as described in the second embodiment, after the supporting substrate 12 is peeled, a part of the insulating film 4 may be removed so that the surface of the electrode portion 2 on the supporting substrate 12 side is exposed.

### Fourth Embodiment

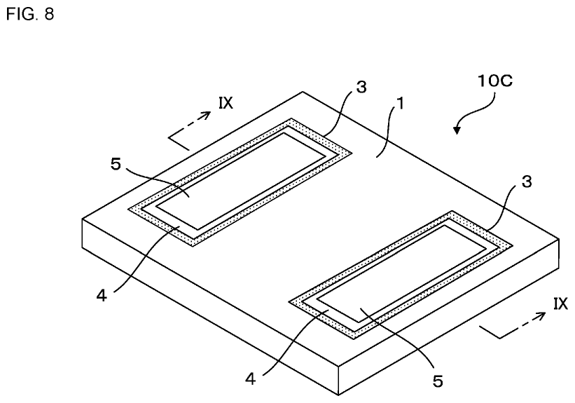

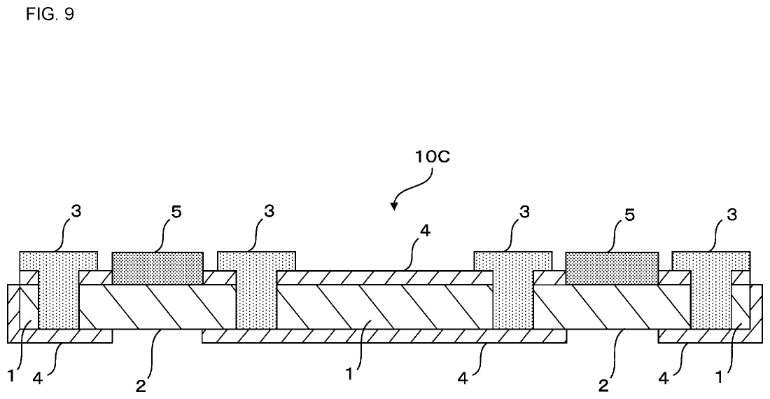

FIG. 8 is a perspective view schematically illustrating a shape of a terminal 10C according to a fourth embodiment. In addition, FIG. 9 is a schematic sectional view of the terminal 10C illustrated in FIG. 8 cut along line IX-IX.

The terminal 10C according to the fourth embodiment further includes a metal film 5 provided so as to cover at least a part of the electrode portion 2.

The metal film 5 is formed of a material having better wettability than the substrate 1 and the electrode portion 2 and includes, for example, at least one selected from the group consisting of Ni, Sn, Cu, Ag, and Au. The metal constituting the metal film 5 may be metal formed of a single element or an alloy containing two or more elements. The thickness of the metal film 5 is, for example, equal to or more than 0.25 μm and equal to or less than 1.2 μm (i.e., from 0.25 μm to 1.2 μm). The metal film 5 may be formed of one layer or may be formed of two or more layers. When the metal film 5 is formed of two or more layers, an influence of dissolution of metallization can be suppressed.

Note that in FIGS. 8 and 9, although an example of a structure in which the terminal 10C includes two electrode portions 2 is illustrated, the terminal 10C may include one electrode portion 2 or three or more electrode portions 2. In addition, although the metal film 5 is provided only on a main surface on one side of the electrode portion 2, the electrode portion 2 may be provided on each main surface.

Since the terminal 10C according to the present embodiment includes the metal film 5 provided so as to cover at least a part of the electrode portion 2, connecting to an electrode of an external circuit, an electronic component element, and the like, and a conductive wire and the like is easily performed. That is, when the metal film 5 is formed of a material having better wettability than the electrode portion 2, connecting to the metal film 5 using solder is easily performed.

Manufacturing Method

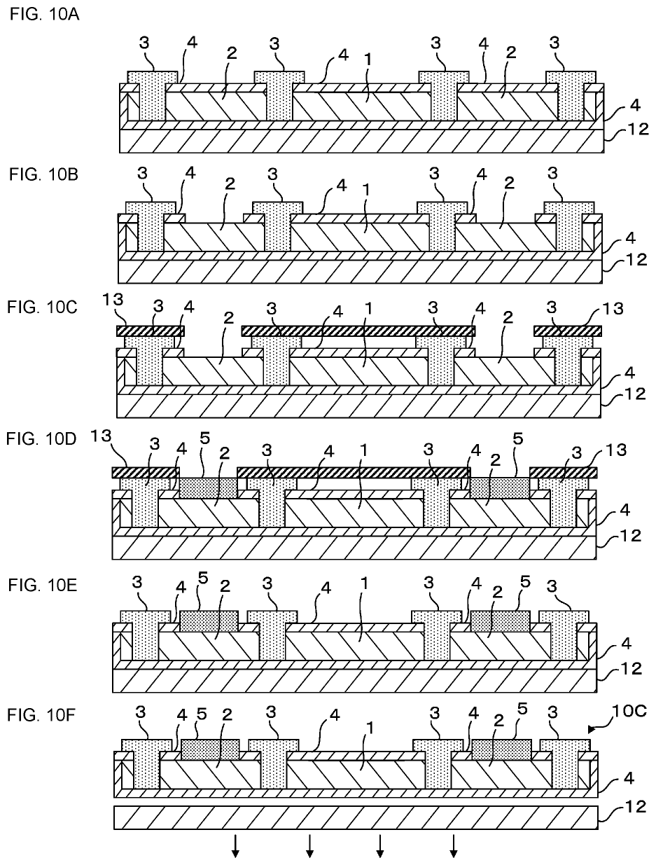

With reference to FIG. 10, an example of a manufacturing method of the terminal 10C according to the fourth embodiment will be described below. Note that a detailed description of the same steps as the manufacturing methods of the terminal 10 according to the first embodiment and the terminal 10A of the second embodiment will be omitted.

First, the insulating film 4 is formed on each surface of the mother substrate 11 made of metal and is adhered and fixed to the supporting substrate 12, and a part of the insulating film 4 is removed by a laser, and then etching is performed on the mother substrate 11 by using the remaining insulating film 4 as a mask so as to provide the groove 20 for dividing the mother substrate 11 into the substrate 1 and the electrode portion 2. Then, the groove 20 formed in the mother substrate 11 is filled with insulating resin and the resin is cured. The steps thus far are the same as the steps in the manufacturing method of the terminal 10A according to the second embodiment, which have been described with reference to FIGS. 5A to 5D. FIG. 10A illustrates a state in which the insulating resin 3 is formed.

Subsequently, in order to expose a surface of the electrode portion 2, a laser is used to remove a part of the insulating film 4 provided on the surface of the electrode portion 2 (FIG. 10B). However, the method of removing a part of the insulating film 4 is not limited to a method using a laser.

Subsequently, the resist 13 is disposed on the surface on an opposite side of the supporting substrate 12, and exposure and development are performed using a photomask to perform patterning on the resist 13 such that a portion of the electrode portion 2 on which the insulating film 4 is removed by the laser is exposed (FIG. 10C).

Subsequently, the metal film 5 is formed on the surface of the electrode portion 2 that is exposed (FIG. 10D). As an example, first, a feeding film made of Cu, Ni, or the like is formed. The feeding film is formed by, for example, sputtering. However, the forming method of the feeding film is not limited to sputtering. The thickness of the feeding film is, for example, equal to or more than 0.05 μm and equal to or less than 0.2 μm (i.e., from 0.05 μm to 0.2 μm).

Subsequently, a plating film is formed on the feeding film by an electrolytic plating method. The plating film includes at least one selected from the group consisting of Ni, Sn, Cu, Ag, and Au. The thickness of the plating film is, for example, equal to or more than 0.2 μm and equal to or less than 1.0 μm (i.e., from 0.2 μm to 1.0 μm).

However, the forming method of the metal film 5 is not limited to the above-described method, and a method such as non-electrolytic plating, sputtering, vapor deposition, or the like may be used.

Subsequently, lift-off is performed to remove the resist 13 (FIG. 10E).

Finally, the supporting substrate 12 is peeled (FIG. 10F).

Through the above-described steps, the terminal 10C according to the fourth embodiment is manufactured. Note that as described in the second embodiment, after the supporting substrate 12 is peeled, a part of the insulating film 4 may be removed so that the surface of the electrode portion 2 on the supporting substrate 12 side is exposed.

Alternatively, as described above, the metal film 5 may be provided on each main surface of the electrode portion 2. In this case, before the supporting substrate 12 is peeled, another supporting substrate 12 is stuck on the surface on an opposite side of the surface on which the supporting substrate 12 is provided, and then the supporting substrate 12 that has been stuck first is peeled, thereby improving the work efficiency. In addition, after the metal film 5 is provided on each main surface of the electrode portion 2, the terminal 10C may be obtained by punching. At this time, a supporting substrate is stuck after the metal film 5 is provided on one main surface of the electrode portion 2, and then the metal film 5 may be provided on another main surface.

Fifth Embodiment

The terminals 10 to 10c according to the first to the fourth embodiments described above can be used for an electronic component package in which an electronic component element is disposed in a sealed container.

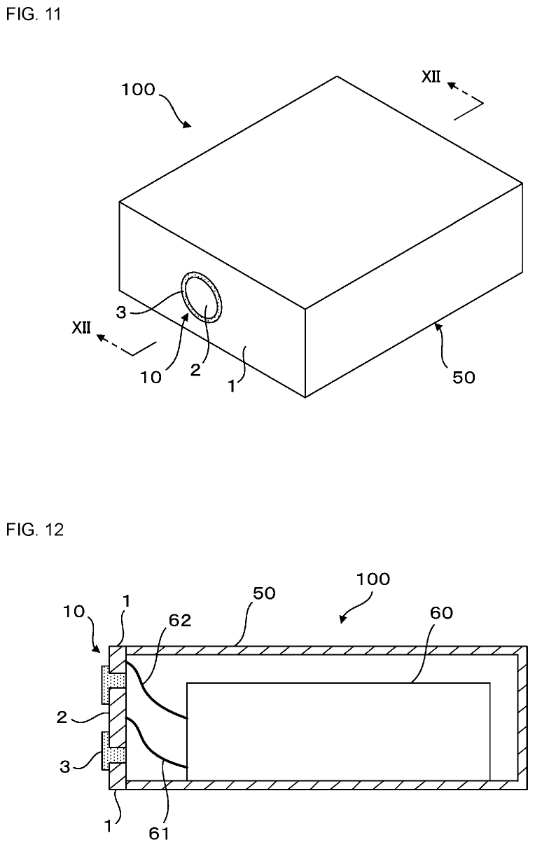

FIG. 11 is a perspective view schematically illustrating a shape of an electronic component package 100 according to a fifth embodiment. FIG. 12 is a schematic sectional view of the electronic component package 100 illustrated in FIG. 11 cut along line XII-XII.

The electronic component package 100 includes a sealed container 50 including the terminal 10, and an electronic component element 60 disposed in the sealed container 50 while being electrically connected to the electrode portion 2. Here, a description is given in consideration that the terminal 10 is the terminal 10 according to the first embodiment, but the terminals 10A to 10C according to the second to the fourth embodiments may be used.

The electronic component element 60 includes a positive electrode terminal 61 and a negative electrode terminal 62. The electronic component element 60 is, for example, a battery element including a positive electrode and a negative electrode. One of the positive electrode terminal 61 and the negative electrode terminal 62 of the electronic component element 60 is electrically connected to the electrode portion 2, and the other is electrically connected to the substrate 1. FIG. 12 illustrates a state in which the positive electrode terminal 61 is electrically connected to the electrode portion 2, and the negative electrode terminal 62 is electrically connected to the substrate 1.

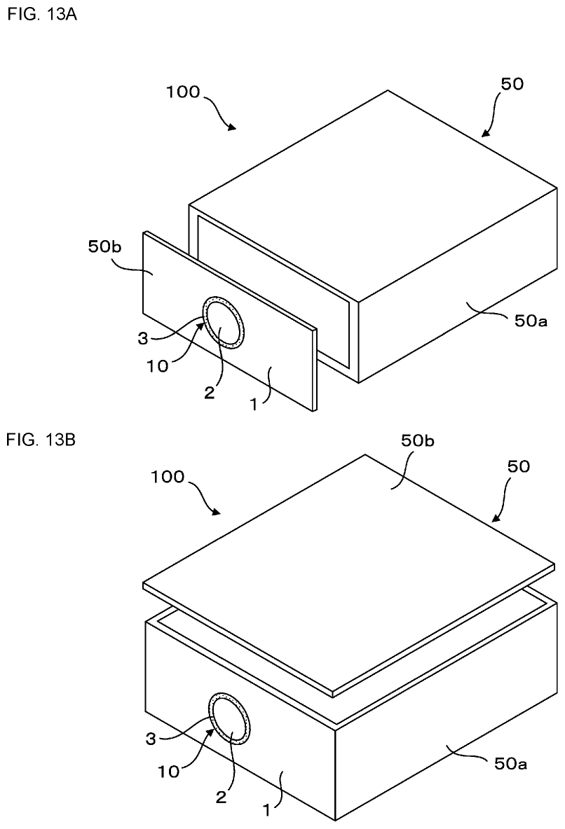

When the sealed container 50 consists of a housing 50a and a lid 50b, the terminal 10 may constitute the lid 50b as illustrated in FIG. 13A or may constitute a part of the housing 50a as illustrated in FIG. 13B. When it is difficult to provide the terminal 10 on a side surface of the housing 50a, a cavity may be provided in a side surface of the housing 50a, and the terminal 10 may be inserted into the cavity and welded. When the terminal 10 constitutes the lid 50b, compared to a case where the terminal 10 is formed as a part of the housing 50a, manufacturing can be easily performed. In either case, the terminal 10 constitutes a part of the sealed container 50. As described above, since the electrode portion 2 of the terminal 10 is formed of the same material as the substrate 1, and the shape of the terminal 10 is less likely to deform when being heated, the sealing property of the sealed container 50 can be maintained.

The housing 50a and the lid 50b are joined by, for example, laser welding. Laser welding is performed, for example, using a fiber laser. The light condensing diameter in this case is, for example, equal to or more than 0.03 mm and equal to or less than 0.1 mm (i.e., from 0.03 mm to 0.1 mm), and the welding speed can be set to, for example, equal to or more than 10 mm/s and equal to or less than 3000 mm/s (i.e., from 10 mm/s to 3000 mm/s). During welding, the laser may be continuously oscillated or may be pulse-oscillated. For example, in order to suppress deformation of the sealed container 50 after welding, a laser may be pulse-oscillated in a state where the pulse width and the pulse frequency are optimized. However, the joining method of the housing 50a and the lid 50b is not limited to laser welding, and other joining methods such as ultrasonic welding, resistance welding, thermal pressure boding, or the like may be used.

Note that in order to prevent a short circuit of the positive electrode terminal 61 and the negative electrode terminal 62, where necessary, an insulating member such as an insulating tape may be interposed between the positive electrode terminal 61, the negative electrode terminal 62, and the terminal 10.

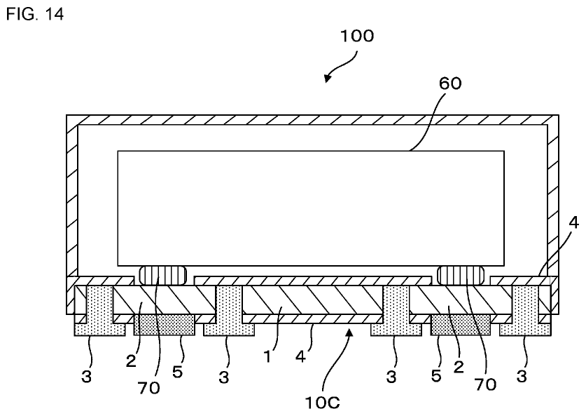

An example of the electronic component package 100 formed using the terminal 10C according to the fourth embodiment will be described below. FIG. 14 is a schematic sectional view when the electronic component package 100 is formed using the terminal 10C according to the fourth embodiment.

The electronic component element 60 is electrically connected to the electrode portion 2 of the terminal 10C with a conductive bump 70 interposed therebetween. For example, a positive electrode terminal of the electronic component element 60 is electrically connected to one of a pair of the electrode portions 2 of the terminal 10C, and a negative electrode terminal of the electronic component element 60 is electrically connected to the other of the pair of electrode portions 2. The metal film 5 provided on a surface of each electrode portion 2 is electrically connected to an electrode of an external circuit, a connective wire, and the like (not illustrated).

The bump 70 may be a solder bump or a conductive adhesive. When the bump 70 is a solder bump, if a surface of the electrode portion 2 is covered with the insulating film 4, the insulating film 4 in a portion where the bump 70 is formed is removed.

In addition, the metal film 5 may be provided on each surface of the electrode portion 2. In this case, since the bump 70 is provided on the metal film 5, compared to a configuration in which the bump 70 is provided without the metal film 5 interposed between the electrode portion 2 and the bump 70, electric resistance can be reduced.

The present disclosure is not limited to the above-described embodiments, and various applications or modifications can be made within the scope of the present disclosure. For example, characteristic configurations in each embodiment can be appropriately combined.

What is claimed is:

1. A terminal comprising:
a substrate made of metal;
an electrode portion that is configured of a same material as the substrate and functions as an electrode; and
an insulating resin that is between the substrate and the electrode portion to surround the electrode portion and insulates the substrate and the electrode portion from each other.

2. The terminal according to claim 1, wherein
the insulating resin is on a part of a surface of the substrate and a part of a surface of the electrode portion on a first main surface side of the substrate, and
the terminal further comprises:
an insulating film between the insulating resin on the first main surface side of the substrate and the substrate and between the insulating resin on the first main surface side of the substrate and the electrode portion.

3. The terminal according to claim 2, wherein
the insulating film is at a position where the insulating film covers at least the insulating resin on a second main surface side facing a first main surface of the substrate.

4. The terminal according to claim 2, wherein
the insulating film is between the insulating resin which surrounds the electrode portion and the electrode portion, and is between the insulating resin which surrounds the electrode portion and the substrate.

5. The terminal according to claim 1, further comprising:
a metal film that covers at least a part of the electrode portion.

6. The terminal according to claim 5, wherein
the metal film includes at least one selected from the group consisting of Ni, Sn, Cu, Ag, and Au.

7. An electronic component package comprising:
a sealed container including the terminal according to claim 1; and
an electronic component element that is in the sealed container while being electrically connected to the electrode portion.

8. The terminal according to claim 3, wherein
the insulating film is between the insulating resin which surrounds the electrode portion and the electrode portion, and is between the insulating resin which surrounds the electrode portion and the substrate.

9. The terminal according to claim 2, further comprising:
a metal film that covers at least a part of the electrode portion.

10. The terminal according to claim 3, further comprising:
a metal film that covers at least a part of the electrode portion.

11. The terminal according to claim 4, further comprising:
a metal film that covers at least a part of the electrode portion.

12. The terminal according to claim 8, further comprising:
a metal film that covers at least a part of the electrode portion.

13. An electronic component package comprising:
a sealed container including the terminal according to claim 2; and
an electronic component element that is in the sealed container while being electrically connected to the electrode portion.

14. An electronic component package comprising:
a sealed container including the terminal according to claim 3; and
an electronic component element that is in the sealed container while being electrically connected to the electrode portion.

15. An electronic component package comprising:
a sealed container including the terminal according to claim 4; and
an electronic component element that is in the sealed container while being electrically connected to the electrode portion.

16. An electronic component package comprising:
a sealed container including the terminal according to claim 5; and
an electronic component element that is in the sealed container while being electrically connected to the electrode portion.

17. An electronic component package comprising:
a sealed container including the terminal according to claim 6; and
an electronic component element that is in the sealed container while being electrically connected to the electrode portion.

18. A manufacturing method of a terminal, the terminal including a substrate made of metal, an electrode portion that is configured of a same material as the substrate and is configured to function as an electrode, and an insulating resin that is between the substrate and the electrode portion to surround the electrode portion and insulates the substrate and the electrode portion from each other, the manufacturing method comprising:
providing a groove for dividing a mother substrate made of metal into the substrate and the electrode portion; and
disposing the insulating resin in the groove.

19. The manufacturing method of a terminal according to claim 18, further comprising:
before the providing of the groove, providing an insulating film on a surface of the mother substrate.

20. The manufacturing method of a terminal according to claim 19, further comprising:
after the providing of the groove and before the disposing of the insulating resin, providing an insulating film on a surface of the groove.
